(19) United States
(12) Patent Application Publication
(10) Pub. No.: US 2009/0021454 A1
(43) Pub. Date: Jan. 22, 2009

(54) DISPLAY DEVICE, AND METHOD FOR REPAIRING A DEFECTIVE PIXEL

(76) Inventors: Tasuku SATOU, Kanagawa (JP); Masaru Kinoshita, Kanagawa (JP)

Correspondence Address: BIRCH STEWART KOLASCH & BIRCH, PO BOX 747, FALLS CHURCH, VA, 22040-0747, US

(21) Appl. No.: 12/173,550

(22) Filed: Jul. 15, 2008

(30) Foreign Application Priority Data
Jul. 20, 2007 (JP) 2007-189965

(51) Int. Cl. H05K 5/02; H01J 9/20; H01J 9/50

(52) U.S. Cl. 345/76; 361/681; 445/2

(57) ABSTRACT

A display device 10 having a supporting substrate 12, pixels arranged over the supporting substrate, each pixel comprising a display element, and a light-transmitting structural body 24 provided on the light extraction side of at least a partial region of at least one of the pixels 22b that is defective and in a constantly non-lit state. The constantly non-lit defective pixel of pixels arranged over the supporting substrate is specified by an examination. The light-transmitting structural body is provided on the light extraction side of at least the partial region of the at least one constantly non-lit defective pixel.

### CROSS REFERENCE TO RELATED APPLICATION

This application claims priority under 35USC 119 from Japanese Patent Application No. 2007-189965, the disclosure of which is incorporated herein by reference.

### BACKGROUND OF THE INVENTION

1. Field of the Invention

The invention relates to a display device, and a method for repairing a defective pixel, in particular, a method capable of repairing a defective pixel easily even if the pixel is in a constantly non-lit state.

2. Description of the Related Art

In recent years, organic EL display devices have been developed wherein pixels are made of organic EL elements (organic electroluminescence elements). Organic EL elements have characteristics that the elements emit light, the elements may be made very thin, the elements are light weight, and the elements have a wide viewing angle and a high-speed responsibility. Thus, the organic EL display devices are expected as the next-generation thin display devices. However, as the performance of liquid crystal display devices has become higher and the cost thereof has become lower, the performances and the price required for organic EL display devices have been becoming severer. In particular, from the viewpoint of costs, organic EL display devices are more expensive than liquid crystal display devices, the mass-producing technique of which has been established. Thus, it is urgently necessary to reduce the costs thereof.

One of factors of an increase in costs of organic EL display devices is that the yield thereof is low. Factors of lowering the yield of organic EL display devices are various. In particular, the yield is lowered by defects of pixels in many cases. The pixel defects are caused by the generation of a short circuit based on dust or dirt, the contact of a mask for dividing pixels into different colors with the pixels, a failure in light exposure based on dust or dirt. Owing to such pixel defects, pixels in a screen partially come not to emit light, or partially are in a constantly lit state which is unable to be controlled.

A device is deemed defective even when only a a minority of pixels in a screen are defective as described above. For this reason, methods of preventing the contact of pixels with dust or dirt, or a mask, thereby decreasing defects are known. However, it is difficult to remove defective pixels completely, and a great improvement in yield is not easily attained. Thus, the following are suggested as a method for repairing defective pixels: a method of applying a high-voltage pulse to a short-circuited moiety to make the moiety electrically nonconductive, thereby restoring the pixels therein to normal pixels (see Japanese Patent Application Laid-Open (JP-A-) No. 11-162637); and a method of radiating a laser ray to defective pixels to repair the pixels (see, for example, JP-A Nos. 2007-42498 and 2006-323032). When an electric current is constantly supplied to an EL element due to, for example, a short circuit of a driving transistor so that the EL element is in a constantly lit state, only a current-supplying line for the pixel made of this EL element is cut by a laser, thereby changing the constantly lit pixel to a constantly non-lit pixel and making the defect inconspicuous. However, if an image appears on the screen in which all pixels adjacent thereto are luminous and with a high brightness, the constantly non-lit pixel conversely becomes a conspicuous defect.

Suggested are also a method of setting up, for an expected defect, a preliminary storage capacitance or switching element, and a method of constructing pixels prepared for a case where some of the pixels become defect pixels (see, for example, JP-A Nos. 2005-92154 and 2003-15549). However, according to such a method, it becomes necessary to prepare extra defect-overcoming measures also for normal pixels, which are most of the entire pixels. As a result, the number of the producing steps increases to raise costs, the definition of the pixels deteriorates, the pixel numerical aperture lowers, and other inconveniences are caused. Thus, the method is not an easy method. Additionally, no countermeasures are taken for pixel defects based on an unexpected inferiority; thus, the defects may not be repaired.

### SUMMARY OF THE INVENTION

The present invention has been made in view of the above-mentioned circumstances and provides the following display device and method for repairing a defective pixel.

A first aspect of the invention, provided is a display device having: a supporting substrate, pixels arranged over the supporting substrate, each pixel comprising a display element, and a light-transmitting structural body provided on the light extraction side of at least a partial region of at least one of the pixels that is defective and in a constantly non-lit state.

A second aspect of the invention, provided is a method for repairing a defective pixel, having: specifying at least one pixel of pixels arranged over a supporting substrate in a display device, the at least one pixel being defective and in a constantly non-lit state, and providing a light-transmitting structural body on the light extraction side of at least a partial region of the at least one constantly non-lit defective pixel.

### BRIEF DESCRIPTION OF THE DRAWINGS

FIG. 1 is a schematic view illustrating an example of a display device according to the present invention wherein a light-transmitting structural body is arranged.

FIG. 2 is a schematic view illustrating another example of the light-transmitting structural body.

FIG. 3 are a chart showing an example of a producing process of a display device according to the invention.

FIG. 4 is a view illustrating an example of the circuit structure of an active matrix driving device.

FIG. 5 is a schematic view illustrating an example of the arrangement of a light-transmitting structural body.

### DETAILED DESCRIPTION OF THE INVENTION

With reference to the attached drawings, the display device and the method for repairing a defective pixel according to the invention will be described hereinafter.

The inventors, in their quest for an ideal repairing method, have discovered that when a light-transmitting structural body is arranged over a constantly non-lit defective pixel so that light emitted from one or more pixels adjacent to the defective pixel is viewed from the constantly non-lit pixel, the following may be attained: when a pixel adjacent to the defective pixel does not emit light, the defective pixel is viewed as it is, that is, as a defective pixel which does not emit light; and when the adjacent pixel emits light, the defective pixel is caused to be viewed as if itself is also emits light.

The invention has subsequently been achieved by repeated research and investigation on the part of the inventors.

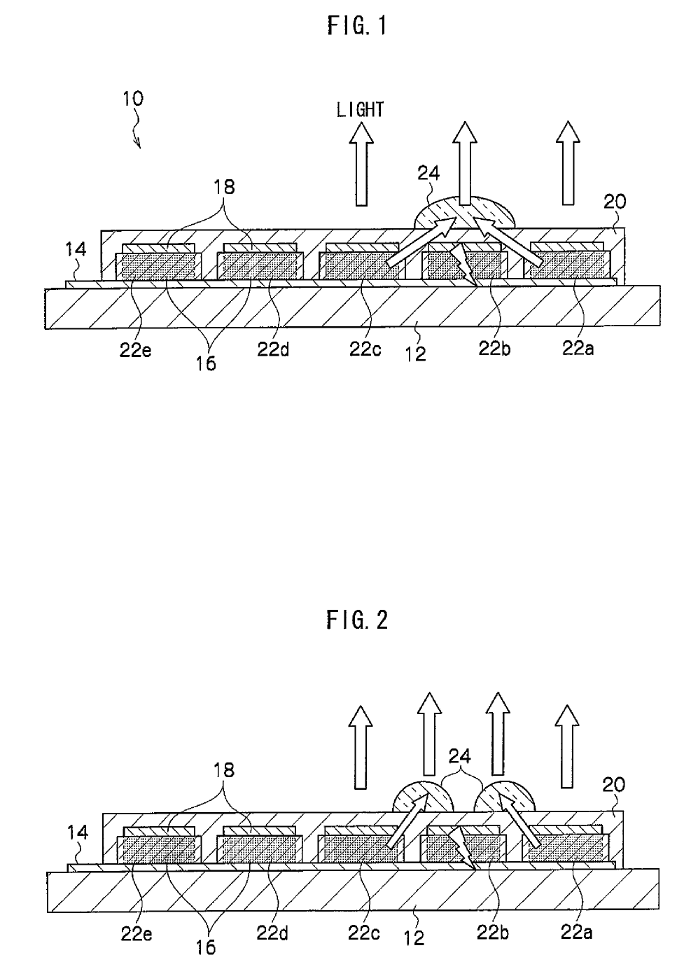

FIG. 1 is a schematic view illustrating an example of the display device according to the invention. In FIG. 1, TFTs and so on, which are necessary for the present description, are omitted. In this display device 10, organic EL elements are formed as display elements. The display device 10 has a supporting substrate 12, a pair of electrodes 14 and 18 arranged over the supporting substrate 12 in the thickness direction thereof, and an organic EL layer 16 containing a light emitting layer and sandwiched between the pair of the electrodes 14 and 18. The light emitting layer moieties sandwiched between the electrodes 14 and 18 emit light. Pixels 22a to 22e made of organic EL elements having the above-mentioned structure are arranged lengthwise and crosswise on the supporting substrate 12. A light-transmitting structural body 24 is arranged on the light extraction side of the defective pixels 22b turned into a constantly non-lit state (one of the pixels 22b being illustrated) out of the pixels 22a to 22e arranged on the supporting substrate 12. In such a way, in the constantly non-lit defective pixels 22b, the light-transmitting structural body 24 is selectively arranged on the light extraction side of their defective moieties regardless of the kind of the defects and a cause thereof, whereby the constantly non-lit defective pixels 22b may be made substantially inconspicuous.

It is not necessarily essential to arrange the light-transmitting structural body 24 on the light extraction side of the entire regions of the non-lit defective pixels 22b. It is sufficient that the light-transmitting structural body 24 is arranged on the light extraction side of a part of the entire regions. For example, as illustrated in FIG. 2, plural pieces which constitute the light-transmitting structural body 24 may be arranged on the light extraction side of partial regions of the constantly non-lit defective pixels 22b.

The following will describe a method for repairing one or more defective pixels when an organic EL display device as described above is produced, and will more specifically describe the display device according to the invention.

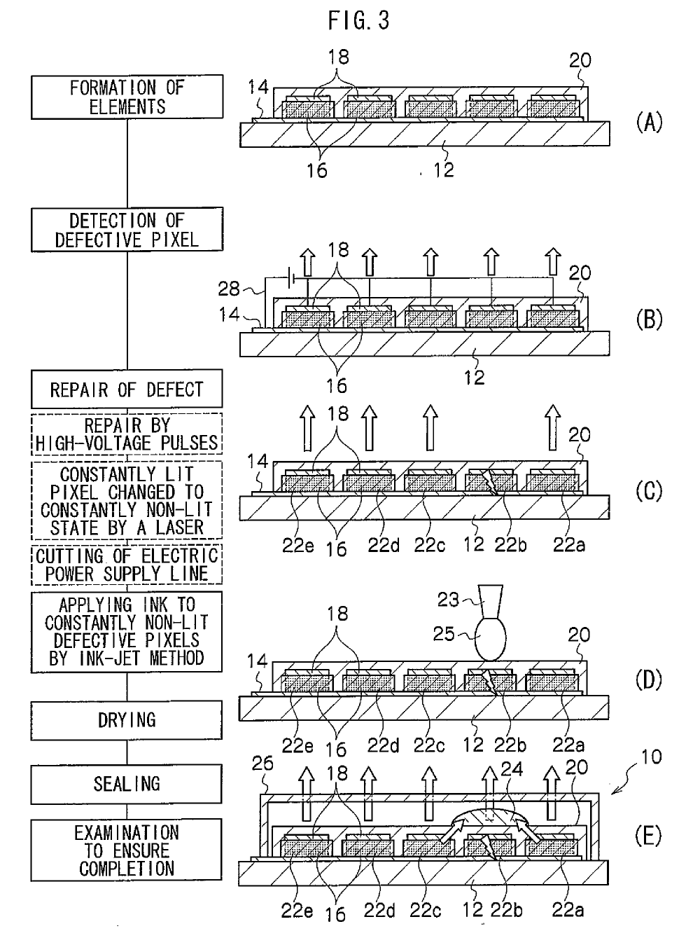

FIG. 3 is a flowchart showing an example of the method for repairing one or more defective pixels according to the invention.

<Supporting Substrate>

The supporting substrate 12 is not particularly limited as long as the substrate is a member having a strength capable of supporting members constituting the organic EL elements, light transmissibility and the like. The supporting substrate 12 may be a known supporting substrate. Examples of the material thereof include inorganic materials such as zirconia stabilized yttrium (YSZ), and glass; and organic materials such as, polyester such as polyethylene terephthalate, polybutylene phthalate, polyethylene naphthalate and the like, polystyrene, polycarbonate, polyethersulfone, polyarylate, polyimide, polycycloolefin, norbornene resin, and poly(chlorotrifluoroethylene).

When a substrate made of glass is used as the supporting substrate 12, the glass is preferably non-alkali glass in order to decrease ions eluted from the glass. When soda lime glass is used, it is preferred to provide a barrier coat such as silica on the glass.

In the case of using the supporting substrate 12 made of an organic material, it is preferred that the substrate 12 is excellent in heat resistance, dimension stability, solvent resistance, electric non-conductance and workability. In the case of using, in particular, a plastic supporting substrate, it is preferred to form a moisture permeation preventing layer or a gas barrier layer onto one side or both sides of the supporting substrate 12 in order to restrain the permeation of moisture or oxygen. The material of the moisture permeation preventing layer or the gas barrier layer is preferably an inorganic material such as silicon nitride or silicon oxide. The moisture permeation preventing layer or the gas barrier layer may be formed by, for example, high-frequency sputtering.

In the case of using a thermoplastic supporting substrate, a hard coat layer, an undercoat layer or the like may be formed thereon as the need arises.

The shape, the structure, the size and other characters of the supporting substrate 12 are not particularly limited, and these may be appropriately selected in accordance with the use manner and the use purpose of the organic EL display device 10. In general, the shape of the supporting substrate 12 is preferably a plate-like shape from the viewpoint of the handleability, the easiness of the formation of the organic EL elements. The structure of the supporting substrate 12 may be a monolayer structure or a laminated structure. The supporting substrate 12 may be made of a single member, or two or more members.

In general, organic EL display devices are classified into: a bottom emission type, in which light emitted from a light emitting layer is extracted from the supporting substrate side of a display device; and a top emission type, in which the same light is extracted from the side opposite to the supporting substrate side. The invention is advantageously applied to display devices wherein display elements constituting pixels are elements of a spontaneously light emitting type, such as organic EL elements. In the invention, any one of the two types may be adopted. As the distance between defective moieties and the light-transmitting structural body 24 is smaller in the invention, the light-transmitting structural body 24 more easily becomes consistent with the defective moieties when the display device is obliquely viewed. In other words, when the distance between the light-transmitting structural body 24 and the light emitting layer is small, the existence of the defective pixels 22b may be made inconspicuous independently of viewing angles. The distance between the light emitting layer of the defective pixels 22b and the light-transmitting structural body 24 is preferably from 0.01 to 1000 μm, more preferably from 0.05 to 300 μm, even more preferably from 0.1 to 50 μm.

The top emission type is particularly advantageous since the light-transmitting structural body 24 may be arranged very closely to the light emitting layer regardless of the thickness of the supporting substrate 12. In the case of producing a top emission type organic EL display device, it is unnecessary that light is extracted from the supporting substrate 12 side; thus, it is allowable to use a metallic supporting substrate made of, for example, stainless steel, Fe, Al, Ni, Co, Cu, or an alloy thereof. The metallic supporting substrate has a high strength, flexibility, and a high gas barrier property against water and oxygen in the atmosphere even if the substrate is thin. In the case of using the metallic supporting substrate, it is necessary to dispose an electrically insulating film in order to keep electric non-conductance surely between the supporting substrate 12 and the lower electrode 14.

<Organic EL Element>

The organic EL elements have a structure wherein the pair of the electrodes (the lower electrode 14 and the upper electrode 18) is arranged over the supporting substrate 12 in the thickness direction thereof, and the organic EL layer 16, which contains the light emitting layer, is sandwiched between the pair of the electrodes 14 and 18. For the organic EL elements, layer structures as described below may be adopted. However, the layer structure of the elements is not limited thereto, and may be appropriately decided in accordance with the use purpose of the display device.

Anode/light emitting layer/cathode

Anode/hole transporting layer/light emitting layer/electron transporting layer/cathode

Anode/hole transporting layer/light emitting layer/blocking layer/electron transporting layer/cathode

Anode/hole transporting layer/light emitting layer/blocking layer/electron transporting layer/electron injecting layer/cathode

Anode/hole injecting electrode/hole transporting layer/light emitting layer/blocking layer/electron transporting layer/cathode

Anode/hole injecting layer/hole transporting layer/light emitting layer/blocking layer/electron transporting layer/electron injecting layer/cathode

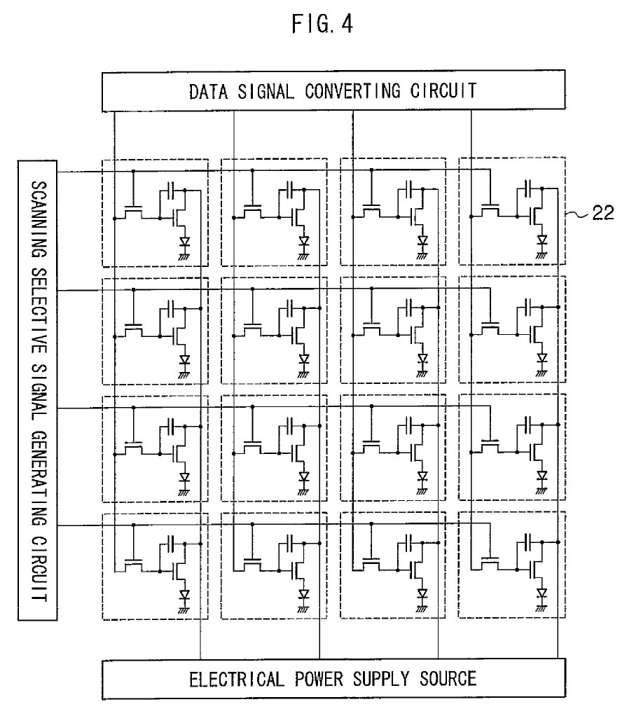

In general, driving methods of organic EL display devices are classified into an active matrix driving and a passive matrix driving. In the invention, any one of the driving types may be adopted. The invention is particularly effective for producing active matrix driving display devices. FIG. 4 illustrates an example of the circuit structure of an active matrix driving method. In general, in an active matrix driving circuit structure, for each pixel 22, an element-driving circuit is formed which has a thin film transistor (TFT) containing a switching element and a driving element, and a capacitor for storing data. Electric current is supplied to the pixels selected through scanning lines and data lines so that the pixels emit light. This manner of active matrix driving display device has the advantages of low power consumption and a high image quality. However, production costs are high; and when defective pixels in a constantly non-lit state are generated by problems with a TFT, it is very difficult to repair the pixels in a known manner, such as by radiation with a laser. In the invention, however, a light-transmitting structural body is provided on the light extraction side of a defective pixel, whereby the existence of the defective pixel may be made inconspicuous. For this reason, even if defective pixels caused by problems with a TFT are present, the pixels may easily be repaired at low costs.

In passive matrix driving display devices, an area which emits no light (a dark spot) may be generated by, for example, exfoliation between an electrode and an organic EL layer, or when a portion of pixels becomes non-luminous upon repair using a laser. In these cases, this defect may easily be repaired by providing a light-transmitting structural body according to the invention at the pertinent area or portion.

<Electrodes>

The pair of electrodes 14 and 18 on the supporting substrate 12 are arranged to sandwich the organic EL layer 16 therebetween. One of the electrodes is an anode and the other is a cathode. It is necessary that the light transmissibility of the electrode on one side of the device from which light emitted from the light emitting layer is extracted is high. Usually, a transparent anode is formed; however, it is also possible to form a transparent cathode and extract light from the cathode side of the device.

—Anode—

The anode is not particularly limited about the shape, the structure, the size and other characters as long as the anode is a member having a function of an electrode for supplying holes to the organic EL layer 16. The anode may be appropriately selected from known electrode materials in accordance with the use manner and the use purpose of the organic EL display device 10.

Preferred examples of the material which constitutes the anode include metals, alloys, metal oxides, electroconductive compounds, and mixtures thereof. Specific examples thereof include electroconductive metal oxides such as tin oxide doped with antimony or fluorine (ATO, or FTO), tin oxide, zinc oxide, indium oxide, indium tin oxide (ITO), and indium zinc oxide (IZO); metals such as gold, silver, chromium, and nickel; mixtures or laminates each composed of two or more selected from the metals and the electroconductive metal oxides; electroconductive inorganic materials such as copper iodide and copper sulfide; electroconductive organic materials such as polyaniline, polythiophene, and polypyrrole; and laminates each composed of one or more selected from these materials, and ITO. Among these materials, electroconductive metal oxides are preferred. ITO is particularly preferred from the viewpoint of productivity, high electric conductivity, and transparency.

Examples of the method for forming the anode include wet methods such as printing and coating methods; physical methods such as vacuum deposition, sputtering, and ion plating; and chemical methods such as CVD and plasma CVD. The method may be appropriately selected, considering suitability for the material which constitutes the anode. When ITO is used as the anode material, for example, the anode may be formed by DC or high frequency sputtering, vacuum deposition, ion plating or the like.

The position where the anode is formed may be appropriately selected in accordance with the use manner and the use purpose of the organic EL display device 10. The anode may be formed on the whole of the supporting substrate 12, or on a partial region thereof.

When the anode is formed, patterning may be performed by chemical etching based on photolithography or the like, or by physical etching using a laser or the like. The patterning may be performed by vacuum vapor deposition, sputtering or the like in the state that a mask is put on the anode material. The patterning may be performed by a liftoff method or a printing method.

The thickness of the anode may be appropriately selected in accordance with the material which constitutes the anode, and is usually from about 10 nm to 50 μm, preferably from 50 nm to 20 μm.

The resistivity of the anode is preferably from 10³Ω/□ or less, more preferably 10²Ω/□ or less in order to supply holes certainly to the organic EL layer 16.

When light is extracted from the anode side, the light transmissibility of the anode is preferably 60% or more, more preferably 70% or more. Transparent anodes are described in detail in “New Development of Transparent Electrode Films”, supervised by Yutaka Sawada, published by CMC Publishing Co., Ltd. (1999). Matters described therein may be applied to the invention. In the case of using, for example, a low heat-resistant supporting substrate made of a plastic, ITO or IZO is used. A transparent anodes made into a film form at a low temperature of 150° C. or lower is preferred.

—Cathode—

The cathode usually has an electrode function of supplying electrons to the organic EL layer 16, and is not particularly limited about the shape, the structure, the size. The cathode may be appropriately selected from known electrodes in accordance with the use manner and the use purpose of the organic EL display device 10. Examples of the material which constitutes the cathode include metals, alloys, metal oxides, electroconductive compounds, and mixtures thereof. Specific examples include alkali metals (such as Li, Na, K and Cs), alkaline earth metals (such as Mg, and Ca), gold, silver, lead, aluminum, sodium-potassium alloy, lithium-aluminum alloy, magnesium-silver alloy, and rare earth metals such as indium, and ytterbium. These may be used alone. In order to make the stability and the electron-injecting performance of the cathode compatible with each other, they are preferably used in combination of two or more thereof.

Of these materials, alkali metals or alkaline earth metals are preferred as the material which constitutes the cathode from the viewpoint of electron injecting performance. From the viewpoint of excellent storage stability, a material made mainly of aluminum is preferred. The material made mainly of aluminum is aluminum alone, an alloy composed of aluminum and 0.01 to 10% by mass of an alkali metal or alkaline earth metal, or a mixture composed of aluminum and such a metal (for example, lithium-aluminum alloy or magnesium-aluminum alloy). The material of the cathode is described in detail in, for example, JP-A Nos. 2-15595 and 5-121172. The materials described in these publications may be used in the invention.

The method for forming the cathode is not particularly limited. Thus, the cathode may be formed by a known method. The cathode may be formed by a method selected appropriately from wet methods such as printing and coating methods, physical methods such as vacuum vapor deposition and sputtering, ion plating, chemical methods such as CVD and plasma CVD, considering suitability for the material which constitutes the cathode. In the case of selecting, for example, a metal as the material of the cathode, the cathode may be formed, for example, by sputtering a single species, or sputtering two or more species simultaneously or successively.

In the case of using the upper electrode 18, for example, as a cathode to produce a top emission display device, it is necessary to form a light transmitting cathode in such a manner that light from the light emitting layer may be extracted from the side opposite to the supporting substrate 12 side. In the case of using the upper electrode 18 as a cathode, a transparent cathode made of ITO may be formed. For example, a laminated film composed of a thin Ag film and a thin Al film may be used to form a transparent cathode having a high light transmissibility. The cathode in the invention may have a bilayered structure composed of a thin metal layer and a transparent conductive layer ill order to make the electron injection property and the transparency consistent with each other.

The thickness of the cathode may be appropriately selected in accordance with the material which constitutes the cathode, or the direction along which light is extracted. The thickness is usually from about 1 nm to 5 μm. In a case where the cathode is a transparent cathode, the thickness is preferably from 1 to 50 nm. When the thickness is in this range, the cathode is easily made into the form of a homogeneous film and the cathode may keep a high light transmissibility certainly.

When the cathode is formed, patterning may be performed by chemical etching based on photolithography or the like, or by physical etching using a laser or the like. The patterning may be performed by vacuum vapor deposition, sputtering or the like in the state that a mask is put on the cathode material. The patterning may be performed by a liftoff method or a printing method.

The position where the cathode is formed is not particularly limited. The cathode may be formed on the whole of the organic EL layer 16, or on a partial region thereof.

<Organic EL Layer>

The organic EL layer 16 sandwiched between the upper and lower electrodes (anode and cathode) 14 and 18 is an organic compound layer containing at least a light emitting layer (light emitting region). As described above, examples of the layer which constitutes the organic EL layer 16 and is different from the light emitting layer include a hole transporting layer, an electron transporting layer, a charge blocking layer, a hole injecting layer, and an electron injecting layer. A preferred embodiment of the layer structure of the organic EL layer is an embodiment wherein from the anode side of the display device a hole transporting layer, a light emitting layer and an electron transporting layer are successively laminated. The display device may have a charge blocking layer or the like, for example, between the hole transporting layer and the light emitting layer or between the light emitting layer and the electron transporting layer. The device may have a hole injecting layer between the anode and the hole transporting layer, or an electron injecting layer between the cathode and the electron transporting layer. Each of the layers may be divided to a plurality of secondary layers.

Each of the layers which constitute the organic EL layer 16 may be preferably formed by any method selected from dry film-forming methods such as vapor deposition or sputtering, a transferring method, a printing method.

—Light Emitting Layer—

The light emitting layer is a layer having a function of receiving holes from the anode, the hole injecting layer or the hole transporting layer and receiving electrons from the cathode, the electron injecting layer or the electron transporting layer when an electric field is applied to the display device, so as to supply a field where the holes are recombined with the electrons.

The light emitting layer may be made only of a light emitting material, or may be made of a mixture of a host material and a light emitting material. Furthermore, the light emitting layer may contain therein a material which has no electron transportability and emits no light. The light emitting layer may be made of a single layer, or two or more secondary layers. The secondary layers may emit light rays in different colors, respectively.

The light emitting material may be a fluorescence emitting material or a phosphorescence emitting material, and may be doped with one or more dopants.

Examples of the fluorescence emitting material include benzoxazol derivatives, benzimidazole derivatives, benzothiazole derivatives, styrylbenzene derivatives, polyphenyl derivatives, diphenylbutadiene derivatives, tetraphenylbutadiene derivatives, naphthalimide derivatives, coumarin derivatives, condensed aromatic compounds, perynone derivatives, oxadiazole derivatives, oxazine derivatives, aldazine derivatives, pyridine derivatives, cyclopentadiene derivatives, bisstyrylanthracene derivatives, quinacridon derivatives, pyrrolopyridine derivatives, thiadiazolopyridine derivatives, cyclopentadiene derivatives, styrylamine derivatives, diketopyrrolopyrrole derivatives, aromatic dimethylidyne compounds, various metal complexes, typical examples of which include metal complexes of an 8-quinolinol derivative, and metal complexes of a pyrromethene derivative, polymeric compounds such as polythiophene, polyphenylene and polyphenylenevinylene, and organic silane derivatives.

Examples of the phosphorescence emitting material include complexes each containing a transition metal atom or a lanthanoid atom.

The transition metal atom is not particularly limited, and is preferably ruthenium, rhodium, palladium, tungsten, rhenium, osmium, iridium, or platinum, more preferably rhenium, iridium or platinum.

Examples of the lanthanoid atom include lanthanum, cerium, praseodymium, neodymium, samarium, europium, gadolinium, terbium, dysprosium, holmium, erbium, thulium, ytterbium, and lutetium. Of these lanthanoid atoms, neodymium, europium and gadolinium are preferred.

Examples of the ligand of the complexes include ligands described in G. Wilkinson et al., “Comprehensive Coordination Chemistry”, published by Pergamon Press Co. in 1987; H. Yersin, “Photochemistry and Photophysics of Coordination Compounds”, published by Springer-Verlag Co. in 1987; and Akio Yamamoto, “Organometallic Chemistry—Foundation and Application—”, published by Shokabo Publishing Co., Ltd. in 1982.

Preferred specific example of the ligand include halogen ligands (preferably, a chlorine ligand), nitrogen-containing heterocyclic ligands (such as phenylpyridine, benzoquinoline, quinolinol, bipyridyl, and phenanthroline), diketone ligands (such as acetylacetone), carboxylic acid ligands (such as an acetic acid ligand), a carbon monoxide ligand, an isonitrile ligand, and a cyano ligand. More preferred are nitrogen-containing heterocyclic ligands. The above-mentioned complexes may each have a single transition metal atom in the compound thereof, or nay each be a multi-nucleus complex, which has two or more transition metal atoms. The multi-nucleus complex may have different metal atoms simultaneously.

The phosphorescence emitting material is contained in the light emitting layer preferably in a proportion of 0.1 to 40% by mass of the layer, more preferably in a proportion of 0.5 to 20% by mass thereof.

The host material contained in the light emitting layer is preferably all electron transporting material. About the host material, a single species thereof may be used, or two or more species thereof may be used. The host material is composed of, for example, a host material having electron transportability and a host material having hole transportability.

Specific examples of the host material include materials having a carbazole skeleton, materials having a diarylamine skeleton, materials having a pyridine skeleton, materials having a pyrazine skeleton, materials having a triazine skeleton, materials having an arylsilane skeleton, and materials exemplified in items “hole injecting layer, and hole transporting layer”, and “electron injecting layer, and electron transporting layer”, which will be described later.

The thickness of the light emitting layer is not particularly limited. Usually, the thickness is preferably from 1 to 500 nm, more preferably from 5 to 200 nm, even more preferably from 10 to 100 nm.

—Hole Injecting Layer, and Hole Transporting Layer—

The hole injecting layer and the hole transporting layer are each layer having a function of receiving holes from the anode or the anode side of the display device and transporting the holes to the cathode side thereof. Specifically, the hole injecting layer and the hole transporting layer are each preferably a layer containing one or more selected from carbazole derivatives, pyrrole derivatives, indole derivatives, imidazole derivatives, polyarylalkane derivatives, pyrazoline derivatives, pyrazolone derivatives, phenylenediamine derivatives, arylamine derivatives, amino-substituted chalcone derivatives, styrylanthracene derivatives, fluorenone derivatives, hydrazone derivatives, stylbene derivatives, silazane derivatives, aromatic tertiary amine compounds, styrylamine compounds, aromatic dimethylidene compounds, porphyrin compounds, organic silane derivatives, carbon, and various metal complexes, typical examples of which include Ir complexes each having phenylazole or phenylazine as a ligand.

The thickness of each of the hole injecting layer and the hole transporting layer is preferably 500 nm or less in order to make the driving voltage low.

The thickness of the hole transporting layer is preferably from 1 to 500 nm, more preferably from 5 to 200 nm, even more preferably from 10 to 200 nm. The thickness of the hole injecting layer is preferably from 0.1 to 200 nm, more preferably from 0.5 to 200 nm, even more preferably from 1 to 200 nm.

The hole injecting layer and the hole transporting layer may each have a monolayered structure made of one or more selected from the above-mentioned materials, or a multilayered structure composed of plural secondary layers which have the same composition or different compositions.

—Electron Injecting Layer, and Electron Transporting Layer—

The electron injecting layer and the electron transporting layer are each a layer having a function of receiving electrons from the cathode or the cathode side of the display device and transporting the electrons to the anode side. Specifically, the electron injecting layer and the electron transporting layer are each preferably a layer containing one or more selected from triazole derivatives, oxazole derivatives, oxadiazole derivatives, imidazole derivatives, pyridine derivatives, pyrazine derivatives, pyrimidine derivatives, triazine derivatives, quinoline derivatives, quinoxaline derivatives, phthalazine derivatives, phenanthroline derivatives, silole derivatives, fluorenone derivatives, anthraquinodimethane derivatives, anthrone derivatives, diphenylquinone derivatives, thiopyrandioxide derivatives, carbodiimide derivatives, fluorenylidenemethane derivatives, distyrylpyrazine derivatives, aromatic ring tetracarboxylic acid anhydrides such as naphthalene and perylene, phthalocyanine derivatives, various metal complexes, typical examples of which include metal complexes of an 8-quinolinol derivative, metal phthalocyanines, and metal complexes each having benzoxazole or benzothiazole as a ligand, organic silane derivatives.

The thickness of each of the electron injecting layer and the electron transporting layer is preferably 500 nm or less in order to make the driving voltage low.

The thickness of the electron transporting layer is preferably from 1 to 500 nm, more preferably from 5 to 200 nm, even more preferably from 10 to 100 nm. The thickness of the electron injecting layer is preferably from 0.1 to 200 nm, more preferably from 0.2 to 100 nm, even more preferably from 0.5 to 50 nm.

The electron injecting layer and the electron transporting layer may each have a monolayered structure made of one or more selected from the above-mentioned materials, or a multilayered structure composed of plural secondary layers which have the same composition or different compositions.

—Hole Blocking Layer—

The hole blocking layer is a layer having a function of preventing holes transported from the anode side to the light emitting layer from going through to the cathode side. The hole blocking layer adjacent to the light emitting layer at the cathode side of the display device may be formed.

The hole blocking layer may be made of an organic compound, and examples thereof include aluminum complexes such as BAlq, triazole derivatives, and phenanthroline derivatives such as BCP.

The thickness of the hole blocking layer is preferably from 1 to 500 nm, more preferably from 5 to 200 nm, even more preferably from 10 to 100 nm.

The hole blocking layer may have a monolayered structure made of one or more selected from the above-mentioned materials, or a multilayered structure composed of plural secondary layers which have the same composition or different compositions.

A dielectric layer made of a fluoride of an alkali metal or alkaline earth metal, an oxide, or the like may be formed into a thickness of 0.1 to 5 nm between the cathode and the organic EL layer 16. This dielectric layer may be interpreted as a kind of electron injection layer. The dielectric layer may be formed by, for example, vacuum vapor deposition, sputtering, or ion plating.

The lower electrode 14, the organic EL layer 16 and the upper electrode 18 are successively formed over the supporting substrate 12, thereby forming organic EL elements wherein the organic EL layer 16 containing the light emitting layer is sandwiched between the pair of the electrodes 14 and 18. In this way, the pixels 22, wherein display is attached by light emitted from the light emitting layer sandwiched between the electrodes 14 and 18, are arranged lengthwise and crosswise on the supporting substrate 12.

<Protective Layer>

After the organic EL elements are formed, a protective layer 20 is preferably formed on the upper electrode 18. The protective layer 20 is preferably made of a material capable of restraining components which promote a deterioration of the elements, such as water and oxygen, from invading the inside of the elements. Specific examples thereof include metals such as In, Sn, Pb, Au, Cu, Ag, Al, Ti, and Ni; metal oxides such as MgO, SiO, SiO₂, Al₂O₃, GeO, NiO, CaO, BaO, Fe₂O₃, Y₂O₃, and TiO₂; metal nitrides such as SiNₓ, and SiNₓO_{y}; metal fluorides such as MgF₂, LiF, AlF₃, and CaF₂; polymers such as polyethylene, polypropylene, polymethyl methacrylate, polyimide, polyurea, polytetrafluoroethylene, polychlorotrifluoroethylene, polydichlorodifluoroethylene, copolymer made from chlorotrifluoroethylene and dichlorodifluoroethylene, copolymer obtained by copolymerizing tetrafluoroethylene and a monomer mixture containing at least one comonomer, and fluorine-containing copolymers each having, in the copolymer main chain thereof, a cyclic structure; water-absorbing materials having a water absorption of 1% or more; and moisture-proof materials having a water absorption of 0.1% or less.

The method for forming the protective layer 20 is not particularly limited, and may be, for example, a vacuum vapor deposition, sputtering, reactive sputtering, MBE (molecular beam epitaxy), cluster ion beam, ion plating, plasma polymerization (high frequency excited ion plating), plasma CVD, laser CVD, thermal CVD, gas source CVD, coating, printing or transferring method.

The thickness of the protective layer 20 is not particularly limited. In the case of producing, in particular, a top emission type display device, the thickness is preferably from 0.01 to 100 μm, more preferably from 0.1 to 50 μm in order to prevent a fall in the light transmissibility and further make small the distance between the light emitting layer in the defective pixel 22b and the light-transmitting structural body 24.

### <Examination Step>

After the formation of the pixels 22 comprising the organic EL elements, of the pixels arranged on the supporting substrate 12, a defective pixel that is in a constantly non-lit state is detected and specified by an examination.

This examination of the defective pixel may be conducted ill accordance with any method that is capable of ascertaining the kind of the defective pixel and the position thereof. For example, all the pixels may be subjected to defect examination before the device elements are sealed with a sealing member such as a glass can (FIG. 3(B)). A voltage may be applied to the pixels, and then the value of the electric current flowing in each of the pixels may be monitored to measure whether or not the value is within a normal range, or, the luminance of each of the pixels may be measured, whereby it may be determined whether or not each of the pixels is a defective pixel. In such a way, it is possible to detect and specify constantly lit, constantly non-lit, and normal pixels from among all the pixels.

### <Repairing Step>

After the defective pixels are ascertained by the examination, the light-transmitting structural body 24 is provided on the light extraction side of at least a partial region of the constantly non-lit defective pixels 22b. Of all the defective pixels it is preferable to restore to a normal pixel one that can be restored to a normal pixel by a known method. (FIG. 3(C)). For example, a constantly non-lit pixel caused by a short circuit between the upper and lower electrodes may be changed to a normally drivable pixel by removing leakage between the electrodes, using high-voltage pulses or a laser.

On the other hand, it is very difficult to restore a constantly lit pixel resulting from a fault with a TFT or the like to a normal pixel by a known method, such as high-voltage pulses. Thus, it is preferable that a constantly lit pixel, if present, is processed beforehand to a constantly non-lit pixel, for example, by cutting only the electric power supplying line for the constantly lit pixel by a laser, whereby the pixel may be changed to being constantly non-lit. When a constantly lit pixel is processed to a constantly non-lit pixel in such a way before providing the light-transmitting structural body on the defective pixel, the light-transmitting structural body is provided on regions thereof corresponding to each of the defective pixels after the processing, whereby the defective pixels may be repaired.

As described above, a constantly non-lit defective pixel that can be repaired by a laser or the like is repaired to a normal pixel as the need arises, while a constantly lit pixel is changed to a constantly non-lit pixel.

When defective pixels are changed to only constantly non-lit pixels which are unable to be repaired, the light-transmitting structural body 24 is selectively provided on the light extraction side of at least a partial region of the constantly non-lit defective pixels.

The light-transmitting structural body 24 is preferably formed of glass or resin material. Specific examples of the material of the light-transmitting structural body 24 include methyl methacrylate resin (PMMA), and urethane.

Light-transmitting structural body 24 preferably contains a light scattering material. When light-transmitting structural body 24 contains the light scattering material, the light scattering material causes incident light from adjacent pixels 22a and 22c to emit toward the front. Thus, defective pixel 22b is readily viewed as if it spontaneously emits light. Specific examples of the light scattering material include silica gel, and white pigments such as barium sulfate and titanium oxide. The light scattering material may be in the form of particles, and the particle diameter thereof is not particularly limited as long as the particles are capable of producing an effect of scattering light from normal pixels 22a and 22c adjacent to defective pixel 22b. The particle diameter is preferably from 0.01 to 1 μm, more preferably from 0.05 to 0.5 μm.

The thickness of the light-transmitting structural body 24 may be appropriately set. However, if the thickness is too small, the structural body 24 may not sufficiently pick up light from the adjacent pixels 22a and 22c. If the thickness is too large, the defective pixels 22b may be reversely conspicuous. From such a viewpoint, the thickness of the light-transmitting structural body 24 is usually from 1 to 100 μm.

The method for providing the light-transmitting structural body 24 is not particularly limited as long as the method is a method capable of providing the light-transmitting structural body 24 selectively to the defective portion 22b. Examples thereof include inkjet method and screen printing. The method is preferably a wet method. According to, for example, ink-jet method, the light-transmitting structural body 24 may be precisely provided at right moieties even if the size of the pixels is in order of micrometers. For example, as shown in FIG. 3(D), a nozzle 23 is used to jet a PMMA ink 25 (a solvent therein may be, for example, dichloromethane) only onto the defective pixel 22b by an ink-jet method. It is preferred to disperse, into the PMMA ink 25, light light-transmitting particles made of silica gel or the like. The ink composition 25 for light-transmitting structural body is jetted out onto all the defective pixels, and the ink composition is dried. In this way, the light-transmitting structural body 24 may be formed on the defective pixels 22b. As shown in FIG. 3(E), light-transmitting structural body 24 may be provided via protective layer 20; in this case, it is possible to prevent negative effects on an organic EL elements due to ink composition 25 or due to light-transmitting structural body 24 after drying thereof.

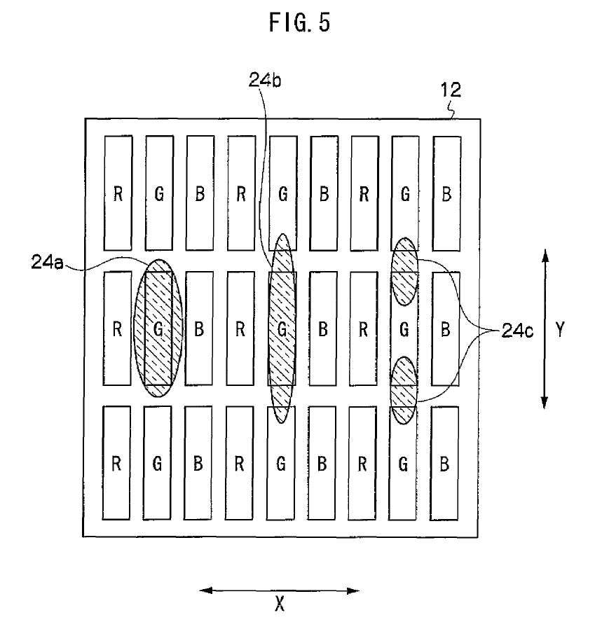

It is sufficient that the light-transmitting structural body 24 is provided on the light extraction side of at least a partial region of the defective pixel 22b. FIG. 5 illustrates an example of the arrangement of the light-transmitting structural body 24 on the defective pixels. In the direction of X on the supporting substrate 12, pixels RGB are repeatedly arranged; in the direction of Y, the pixels are arranged to have the same colors, respectively. In such a pixel arrangement, for example, a light-transmitting structural body 24a may be provided to cover only a defective pixel G. For example, when the distance between the pixels in the same color is beforehand made small, the light-transmitting structural body on the defective pixel easily picks up light from the adjacent pixels in the same luminous color (G). As a result, the defective pixel is more easily viewed as if the pixel emits original color (G).

It is preferable that a light-transmitting structural body on a defective pixel is provided to further overlap with one or more pixels adjacent to the defective pixel. It is particularly preferable that the light-transmitting structural body is provided to further overlap with one or more pixels having the same luminous color as the defective pixel. When a light-transmitting structural body on a defective pixel is provided to overlap with one or more normal pixels adjacent to the defective pixel, when the one or more adjacent pixels emits light, the light is readily incident on the light-transmitting structural body. As a result, the defective pixel is viewed as if it emits light.

For example, a light-transmitting structural body 24b may cover the whole of a defective pixel G and further overlap with a partial region of each of pixels G which are adjacent to the defective pixel G on both sides thereof and are in the same luminous color. Alternatively, each of two light-transmitting structural body 24c may be provided to overlap with a partial region of a defective pixel G and a partial region of each of pixels which are adjacent to the defective pixel G and are in the same luminous color (C). In a case where the light-transmitting structural bodies 24b and 24c on the defective pixels overlap with the normal pixels which are adjacent to the defective pixels and are in the same luminous color, when the adjacent normal pixels emit light, the defective pixels are viewed as if the defective pixels also emit light in the same color. Thus, the defective pixels may be made more inconspicuous.

The shape of the light-transmitting structural body is not limited to the shape illustrated in FIG. 5. For example, the light-transmitting structural body 24b may be provided to overlap with only one of the pixels adjacent to the defective pixel. Only one of the light-transmitting structural body 24c, which covers a partial region of the defective pixel, may be provided. The light-transmitting structural body may be provided to overlap with a pixel which is adjacent to the defective pixel G and has a color (R or B) different from the color of the defective pixel G.

### <Sealing and Others>

After the light-transmitting structural body 24 is provided on the constantly non-lit defective pixel 22b, the whole of the organic EL elements is sealed with a sealing member 26 in order to block invasion of moisture and oxygen from the outside into the display device. Examples of the material used for the sealing member 26 include glass, stainless steel, metals (such as aluminum), plastics (such as polychlorotrifluoroethylene, polyester, and polycarbonate), and ceramics. When the display device is of a top emission type, the sealing member 26 needs to be transparent and the member 26 is preferably a glass can from the viewpoint of the barrier property thereof against oxygen and moisture.

A water absorbent, an inert liquid or the like may be put into the space between the sealing member 26 and the elements in order to prevent a deterioration of the organic EL elements effectively. Specific examples of the water absorbent include barium oxide, sodium oxide, potassium oxide, calcium oxide, sodium sulfate, calcium sulfate, magnesium sulfate, phosphorus pentaoxide, calcium chloride, magnesium chloride, copper chloride, cesium fluoride, niobium fluoride, calcium bromide, vanadium bromide, molecular sieves, zeolite, and magnesium oxide. Examples of the inert liquid include paraffins, liquid paraffins, fluorine-containing solvents (such as perfluoroalkanes, perfluoroamines, and perfluoroethers), chlorine-containing solvents, and silicone oils.

Furthermore, the upper and lower electrodes 14 and 18 are connected to an external power source and circuits (such as a data signal converting circuit and a scanning selective signal generating circuit), and then the resultant is examined for completion. For the driving of the elements, a method described in any one of the following may be used: publications of JP-A Nos. 2-148689, 6-301355, 5-29080, 7-134558, 8-234685 and 8-241047, U.S. Pat. Nos. 5,828,429 and 6,023,308, Japanese Patent No. 2784615, aid other documents.

Through the above-mentioned steps, the organic EL display device 10 may be yielded, wherein the constantly non-lit defective pixels 22b are repaired by effect of the light-transmitting structural body 24. According to the thus-produced organic EL display device 10, light emitted from the adjacent pixels 22a and 22c is diffusely reflected by the light-transmitting structural body 24 on the defective pixels 22b. Thus, the defective pixels 22b are viewed as if it emits light. In other words, the defective pixels 22b pick up light emitted from the adjacent pixels 22a and 22c, which are normal, so that the pixels 22b appear to emit light spontaneously. As a result, the constantly non-lit pixels may be made into a substantially inconspicuous state. The display device thus becomes a display device wherein defects are apparently absent. Moreover, the particular content of the display does not readily allow defects to be seen, and thus the defects are inconspicuous regardless of the image displayed.

As described above, according to the invention, a light-transmitting structural body is provided on the light extraction side of a defective pixel that is in a constantly non-lit state. Thus, constantly non-lit pixels, which have not been easily repaired conventionally, may be substantially affected such that a defect thereof is not substantially recognized. This repairing method may be applied in spite the existence of a cause of the defect of the defective pixel. Thus, the defective pixel may easily be repaired at low costs. Thus, according to the invention, therefore, the yield of display devices may be greatly improved and costs thereof may be decreased. Accordingly, display devices high in quality may be provided at a low cost.

The display device and the method for repairing a defective pixel according to the invention have been described above; however, the invention is not limited to the above-mentioned exemplary embodiments. For example, the exemplary embodiment is concerned with a case where the invention is applied to an organic EL display device of a top emission type. However, the invention may be applied to an organic EL display device of a bottom emission type. Specifically, it is allowable to use a supporting substrate made of a transparent and thin glass or resin piece to produce an organic EL display device of a bottom emission type, and then provide a light-transmitting structural body according to the invention on regions of the supporting substrate which correspond to defective pixels turned to a constantly non-lit state, whereby the defective pixels may be repaired.

The invention may be applied to any display device wherein pixels are arranged on a supporting substrate. The invention may also be applied to, for example, repair of defective pixels in a display device wherein an inorganic EL elements, plasma elements, electrophoresis elements, liquid crystal elements or other pixels are arranged.

The foregoing description of the exemplary embodiments of the present invention has been provided for the purposes of illustration and description. It is not intended to be exhaustive or to limit the invention to the precise forms disclosed. Obviously, many modifications and variations will be apparent to practitioners skilled in the art. The exemplary embodiments were chosen and described in order to best explain the principles of the invention and its practical applications, thereby enabling others skilled in the art to understand the invention for various embodiments and with the various modifications as are suited to the particular use contemplated. It is intended that the scope of the invention be defined by the following claims and their equivalents.

All publications, patent applications, and technical standards mentioned in this specification are herein incorporated by reference to the same extent as if each individual publication, patent application, or technical standard was specifically and individually indicated to be incorporated by reference.

What is claimed is:

1. A display device, comprising:
a supporting substrate,
pixels arranged over the supporting substrate, each pixel comprising a display element, and
a light-transmitting structural body provided on the light extraction side of at least a partial region of at least one of the pixels that is defective and in a constantly non-lit state.

2. The display device of claim 1, wherein the display element is a light emitting display element.

3. The display device of claim 2, wherein the display element is an organic EL element.

4. The display device of claim 1, wherein the light-transmitting structural body overlaps at least one pixel adjacent to the defective pixel.

5. The display device of claim 1, wherein at least two pixels arranged over the supporting substrate are different from each other in luminous color, and the light-transmitting structural body overlaps at least one pixel having the same luminous color as the defective pixel.

6. The display device of claim 3, wherein at least two pixels arranged over the supporting substrate are different from each other in luminous color and the light-transmitting structural body overlaps at least one pixel having the same luminous color as the defective pixel.

7. The display device of claim 1, wherein the display device is a top emission display device, and wherein light from the pixels is extracted from the side opposite to the supporting substrate side of the display device.

8. The display device of claim 6, wherein the display device is a top emission display device, and wherein light from the pixels is extracted from the side opposite to the supporting substrate side of the display device.

9. The display device of claim 1, wherein a protective layer is formed on the display element, and the light-transmitting structural body is provided via the protective layer on the display element.

10. The display device of claim 8, wherein a protective layer is formed on the display element, and the light-transmitting structural body is provided via the protective layer on the display element.

11. The display device of claim 1, wherein the light-transmitting structural body contains a light scattering material.

12. The display device of claim 10, wherein the light-transmitting structural body contains a light scattering material.

13. The display device of claim 1, wherein the distance between a light emission moiety of the defective pixel and the light-transmitting structural body is from 0.1 to 50 μm.

14. The display device of claim 12, wherein the distance between a light emission moiety of the defective pixel and the light-transmitting structural body is from 0.1 to 50 μm.

15. The display device of claim 1, wherein the display device is an active matrix driving display device.

16. The display device of claim 14, wherein the display device is an active matrix driving display device.

17. A method for repairing a defective pixel, comprising:
specifying at least one pixel of pixels arranged over a supporting substrate in a display device, the at least one pixel being defective and in a constantly non-lit state, and
providing a light-transmitting structural body on the light extraction side of at least a partial region of the at least one constantly non-lit defective pixel.

18. The method for repairing a defective pixel of claim 17, wherein the light-transmitting structural body is provided in a wet manner.

19. The method for repairing a defective pixel of claim 17, which comprises processing at least one of the pixels which is in a constantly lit state to a pixel in a constantly non-lit state before providing the light-transmitting structural body.

20. A display device produced by repairing a defective pixel by the method of claim 17.
